(19) United States
(12) Patent Application Publication
(10) Pub. No.: US 2021/0247929 A1
(43) Pub. Date: Aug. 12, 2021

(54) WRITE OPERATION CIRCUIT, SEMICONDUCTOR MEMORY AND WRITE OPERATION METHOD

(71) Applicant: CHANGXIN MEMORY TECHNOLOGIES, INC., Hefei (CN)

(72) Inventor: Liang ZHANG, Hefei (CN)

(21) Appl. No.: 17/243,500

(22) Filed: Apr. 28, 2021

Related U.S. Application Data
(63) Continuation of application No. PCT/CN2020/097350, filed on Jun. 22, 2020.

(30) Foreign Application Priority Data
Oct. 25, 2019 (CN) 201911021589.2

(51) Int. Cl. G06F 3/06

(52) U.S. Cl. CPC G06F 3/0656; G06F 3/0679; G06F 3/0602

(57) ABSTRACT

Embodiments provide a write operation circuit, a semiconductor memory, and a write operation method. The write operation circuit includes: a data determination module, a data buffer, a data receiving module, and a precharge module. The data determination module determines, according to a number of low-level bits in input data of a semiconductor memory, whether to invert the input data to generate inversion flag data and first intermediate data. The data buffer determines, according to second intermediate data, whether to invert a global bus, where the second intermediate data is inverted data of the first intermediate data. The data receiving module decodes global bus data according to the inversion flag data and writes the decoded data into the memory bank, where the decoding includes determining whether to invert the global bus data. The precharge module sets an initial state of the global bus to high.

### CROSS REFERENCE

This application is a continuation of PCT/CN2020/097350, filed on Jun. 22, 2020, which claims priority to Chinese Patent Application No. 201911021589.2, titled “WRITE OPERATION CIRCUIT, SEMICONDUCTOR MEMORY AND WRITE OPERATION METHOD” and filed to the State Intellectual Property Office on Oct. 25, 2019, the entire contents of which are incorporated herein by reference.

### TECHNICAL FIELD

The present disclosure relates to the field of semiconductor memory technologies, and more particularly, to a write operation circuit, a semiconductor memory, and a write operation method.

### BACKGROUND

Semiconductor memory includes Static Random-Access Memory (SRAM), Dynamic Random Access Memory (DRAM), Synchronous Dynamic Random Access Memory (SDRAM), Read-Only Memory (ROM), Flash, and the like.

In the DRAM protocol made by Joint Electron Device Engineering Council (JEDEC), there are specific requirements for speed and power saving of DRAM. How to make DRAM more power-saving while also ensuring the signal integrity and the reliability of data transmission and storage is a problem urgently to be solved in the industry.

### SUMMARY

Embodiments of the present disclosure provide a write operation circuit, a semiconductor memory, and a write operation method to solve or alleviate one or more technical problems in the existing technologies.

In one aspect, embodiments of the present disclosure provide a write operation circuit that is used in a semiconductor memory. The write operation circuit comprises a data determination module, a data buffer, a data receiving module connected to a memory bank, and a precharge module.

The data determination module is configured to determine, according to a number of low-level bits in input data of the semiconductor memory, whether to invert the input data to generate inversion flag data and first intermediate data.

The data buffer comprises a plurality of NMOS transistors and a plurality of first inverters. A gate electrode of each of the plurality of NMOS transistors is connected to the data determination module through a respective one of the plurality of first inverters to receive second intermediate data. A drain electrode of each of the plurality of NMOS transistors is connected to a global bus. The data buffer is configured to determine, according to second intermediate data, whether to invert the global bus, where the second intermediate data is inverted data of the first intermediate data.

The data receiving module receives global bus data through the global bus and receives the inversion flag data through the inversion flag signal line. The data receiving module is configured to decode the global bus data according to the inversion flag data and write the decoded data into the memory bank of the semiconductor memory, and the decoding comprises determining whether to invert the global bus data.

The precharge module connected to a precharge signal line and configured to set an initial state of the global bus to high.

In some embodiments, the write operation circuit further comprises a serial-to-parallel conversion circuit connected between a Data Queue (DQ) port of the semiconductor memory and the data determination module. The serial-to-parallel conversion circuit is configured to perform serial-to-parallel conversion on first input data of the DQ port to generate second input data, and the data determination module is configured to determine, according to a number of low-level bits in the second input data, whether to invert the second input data to generate the inversion flag data and first intermediate data.

In some embodiments, the second input data is divided into M groups, the inversion flag data has M bits, and the M bits of the inversion flag data are in one-to-one correspondence with the M groups of second input data. Each of the M groups of second input data has N bits, N and M are integers greater than 1. When a number of low-level bits in a group of second input data inputted to the data determination module is greater than N/2, the data determination module is configured to output inversion data of the group of second input data as a group of first intermediate data corresponding to the group of second input data and set one bit of the inversion flag data corresponding to the group of second input data to high. When the number of low-level bits in the group of second input data inputted to the data determination module is less than or equal to N/2, the data determination module is configured to output the group of second input data as the group of first intermediate data corresponding to the group of second input data and set one bit of the inversion flag data corresponding to the group of second input data to low.

In some embodiments, the data determination module comprises a data determination unit and a data selector.

An input terminal of the data determination unit is connected to the serial-to-parallel conversion circuit, and an output terminal of the data determination unit is connected to the inversion flag signal line. The data determination unit is configured to set the inversion flag data to high when the number of low-level bits in the second input data is greater than a preset value, and set the inversion flag data to low when the number of low-level bits in the second input data is less than or equal to the preset value.

An input terminal of the data selector is connected to the data determination unit to receive the second input data through the data determination unit, an input terminal of the data selector further receives the inversion flag data through the inversion flag signal line, and an output terminal of the data selector is connected to an input terminal of the first inverter. The data selector is configured to output the inversion data of the second input data as the first intermediate data when the inversion flag data is high, and output the original second input data as the first intermediate data when the inversion flag data is low.

In some embodiments, the data selector includes a plurality of data select units, and each of the plurality of data select units comprises: a second inverter, a third inverter, a first transmission gate, and a second transmission gate.

An input terminal of the second inverter receives the inversion flag data through the inversion flag signal line.

An input terminal of the third inverter is connected to the data determination unit and is configured to receive the second input data from the data determination unit.

An input terminal of the first transmission gate is connected to an output terminal of the third inverter, an output terminal of the first transmission gate is connected to the input terminal of the first inverter and is configured to output the first intermediate data, a negative control terminal of the first transmission gate is connected to an output terminal of the second inverter, and a positive control terminal of the first transmission gate receives the inversion flag data through the inversion flag signal line.

An input terminal of the second transmission gate is connected to the data determination unit and is configured to receive the second input data from the data determination unit, an output terminal of the second transmission gate is connected to the input terminal of the first inverter and is configured to output the first intermediate data, a negative control terminal of the second transmission gate receives the inversion flag data through the inversion flag signal line, and a positive control terminal of the second transmission gate is connected to the output terminal of the second inverter.

In some embodiments, the global bus data is divided into M groups, and the M bits of the inversion flag data are in one-to-one correspondence with the M groups of global bus data. The data receiving module comprises M data receiving units, and each of the M data receiving units is connected to the memory bank and is configured to decode the corresponding group of global bus data according to one bit of the inversion flag data.

In some embodiments, the data receiving unit comprises: a fourth inverter, a fifth inverter, a third transmission gate, and a fourth transmission gate.

An input terminal of the fourth inverter receives the inversion flag data through the inversion flag signal line.

An input terminal of the fifth inverter receives the global bus data through the global bus.

An input terminal of the third transmission gate is connected to an output terminal of the fifth inverter, an output terminal of the third transmission gate is connected to the memory bank and is configured to output the decoded data to the memory bank, a negative control terminal of the third transmission gate is connected to an output terminal of the fourth inverter, and a positive control terminal of the third transmission gate receives the inversion flag data through the inversion flag signal line.

An input terminal of the fourth transmission gate receives the global bus data through the global bus, an output terminal of the fourth transmission gate is connected to the memory bank and is configured to output the decoded data to the memory bank, a negative control terminal of the third transmission gate receives the inversion flag data through the inversion flag signal line, and a positive control terminal of the third transmission gate is connected to the output terminal of the fourth inverter.

In some embodiments, the precharge module comprises a plurality of PMOS transistors and a plurality of hold circuits. A gate electrode of each of the plurality of PMOS transistors is connected to the precharge signal line, a drain electrode of each of the plurality of PMOS transistors is connected to the global bus, and an input terminal and an output terminal of the hold circuit are both connected to the global bus.

In another aspect, embodiments of the present disclosure provide a semiconductor memory, which includes the write operation circuit according to any one of the above embodiments.

In yet another aspect, embodiments of the present disclosure provide a write operation method used in a semiconductor memory. The write operation method comprises:

setting an initial state of a global bus to High;

determining, according to a number of low-level bits in input data of the semiconductor memory, whether to invert the input data to generate inversion flag data and first intermediate data;

determining whether to invert global bus data according to second intermediate data, wherein the second intermediate data is inverted data of the first intermediate data;

decoding the global bus data according to the inversion flag data, where the decoding includes determining whether to invert the global bus data; and

writing the decoded data into a memory bank.

In some embodiments, the step of determining, according to the number of low-level bits in input data of the semiconductor memory, whether to invert the input data to generate the inversion flag data and the first intermediate data comprises:

performing serial-to-parallel conversion on first input data of a DQ port to generate second input data; and

determining, according to a number of low-level bits in the second input data, whether to invert the second input data to generate inversion flag data and first intermediate data.

In some embodiments, the step of determining, according to the number of low-level bits in the second input data, whether to invert the second input data to generate inversion flag data and first intermediate data comprises:

dividing the second input data into M groups, where each group of second input data has N bits, and M and N are integers greater than 1;

when a number of low-level bits in an inputted group of second input data is greater than N/2, outputting inversion data of the inputted group of second input data as a corresponding group of first intermediate data and setting one bit of the inversion flag data corresponding to the inputted group of second input data to high; and

when the number of low-level bits in the inputted group of second input data inputted to the data determination module is less than or equal to N/2, outputting the inputted group of second input data as the corresponding group of first intermediate data and setting one bit of the inversion flag data corresponding to the inputted group of second input data to low.

By using the above technical solutions, the embodiments of the present disclosure can reduce the number of inversions of the global bus in a Precharge-Low architecture, thereby greatly reducing a current and decreasing power consumption.

The above is only for the purpose of description and is not intended to be limiting in any way. In addition to the illustrative aspects, embodiments and features described above, further aspects, embodiments and features of this disclosure can be easily understood by referring to the drawings and the following detailed description.

### BRIEF DESCRIPTION OF THE DRAWINGS

In the drawings, unless otherwise specified, the same reference numerals denote the same or similar parts or elements throughout the multiple drawings. The drawings are not necessarily drawn to scale. It should be understood that these drawings only depict some embodiments disclosed according to the present disclosure, and should not be regarded as limiting of the scope of the present disclosure.

FIG. 1 shows a schematic block diagram of a part of a semiconductor memory according to an implementation of an embodiment of the present disclosure;

FIG. 2 shows a schematic block diagram of a part of a semiconductor memory according to another implementation of the embodiment of the present disclosure;

FIG. 3 shows a schematic circuit diagram of a data buffer and a precharge module (corresponding to one memory bank) according to an implementation of the embodiment of the present disclosure;

FIG. 4 shows a schematic circuit diagram of a data buffer and a precharge module (corresponding to multiple memory banks) according to an implementation of the embodiment of the present disclosure;

FIG. 5 shows a schematic block diagram of a data determination module according to an implementation of the embodiment of the present disclosure;

FIG. 6 shows a schematic block diagram of a data select unit according to an implementation of the embodiment of the present disclosure;

FIG. 7 shows a schematic block diagram of a data receiving module according to an implementation of the embodiment of the present disclosure;

FIG. 8 shows a schematic block diagram of a data receiving unit according to an implementation of the embodiment of the present disclosure; and

FIG. 9 shows a schematic flowchart of a write operation method according to an implementation of the embodiment of the present disclosure.

### REFERENCE NUMERALS IN THE ACCOMPANYING DRAWINGS

20: semiconductor memory;
21: serial-to-parallel conversion circuit;
22: data buffer;
23: data determination module;
24: DQ port;
25: data receiving module;
26: memory bank;
27: precharge module;
221: PMOS transistor;
222: NMOS transistor;
223: hold circuit;
224: first inverter;
231: data determination unit;
232: data selector;
232′: data selection unit;
232A: second inverter;
232B: third inverter;
232C: first transmission gate;
232D: second transmission gate;
250: data receiving unit;
251: fourth inverter;
252: fifth inverter;
253: third transmission gate; and
254: fourth transmission gate.

### DETAILED DESCRIPTION

Exemplary embodiments will be described more comprehensively with reference to the accompanying drawings. However, the exemplary embodiments can be implemented in various forms, and should not be construed as being limited to the embodiments set forth herein. On the contrary, these embodiments are provided so that this disclosure will be comprehensive and complete, and will fully convey the concept of the exemplary embodiments to those skilled in the art. In the drawings, the same reference numerals denote the same or similar elements, and thus their repeated description will be omitted.

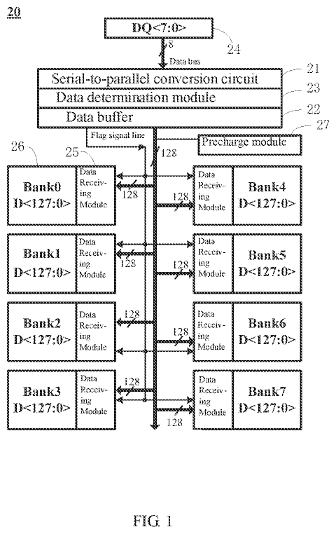

FIG. 1 shows a schematic block diagram of a part of a semiconductor memory according to an implementation of an embodiment of the present disclosure. As shown in FIG. 1, a semiconductor memory 20 includes a DQ port 24, a memory bank 26, and a write operation circuit. The write operation circuit includes a global bus, an inversion flag signal line, a serial-to-parallel conversion circuit 21, a data termination module 23, a data buffer 22, a data receiving module 25, and a precharge module 27. In an implementation, the semiconductor memory 20 is Dynamic Random Access Memory (DRAM), for example, Double Data Rate SDRAM 4 (abbreviated as DDR4).

In an example, as shown in FIG. 1, the write operation circuit receives 8-bit first input data DQ<7:0> through the DQ port 24, and writes write data (i.e., decoded data) D<127:0> into the memory bank 26. One Active command enables the only one designated memory bank 26. The write operation is executed per memory bank 26. That is, when one memory bank of eight memory banks 26 (i.e., Bank<7:0>) is working, the other memory banks are not working. It should be noted that, the number of the memory banks 26, the number of data bits of each memory bank 26, the number of data bits of the DQ port 24, and the number of the DQ port 24 are not limited in embodiments of the present disclosure. For example, there may be one DQ port 24 for inputting 8-bit first input data. For another example, there may be two DQ ports 24, which are respectively used for inputting 8-bit first input data DQ<7:0> and 8-bit first input data DQ<15:8>, and thus 16-bit first input data DQ<15:0> is inputted.

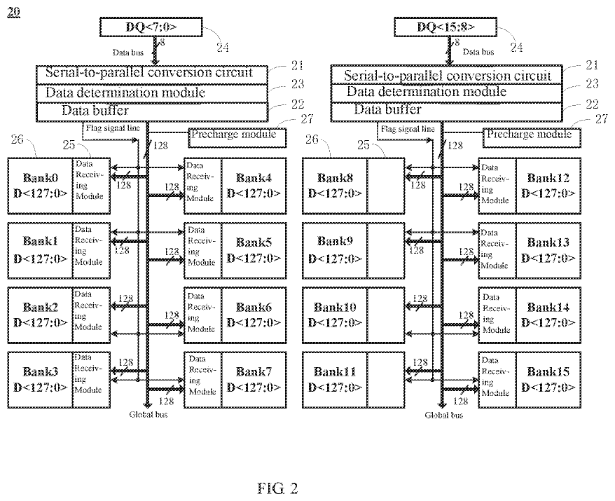

In another example, as shown in FIG. 2, write operation of the first input data DQ<7:0> for a group of memory banks <7:0> is executed by one write operation circuit, and write operation of the first input data DQ<15:8> for another group of memory banks <15:8> is executed by another write operation circuit. Accordingly, among the eight memory banks 26 (i.e., Bank<15:8>) corresponding to DQ<15:8>, only one memory bank is working, the other memory banks are not working.

The semiconductor memory 20 is in an array structure, and the structure of each unit may be the same. However, the output data of the units may be different due to different input data. The write operation circuit of the present embodiment is described below by taking one memory bank as an example.

As shown in FIG. 1 and FIG. 2, the write operation circuit of the present embodiment includes a data determination module 23, and the data determination module 23 is configured to determine, according to the number of low-level bits in the input data of the semiconductor memory 20, whether to invert the input data to generate inversion flag data and first intermediate data.

In an implementation, when the number of low-level bits in the input data is greater than a preset value, the data determination module 23 is configured to output inversion data of the input data as the first intermediate data and set inversion flag data (Flag) to High; when the number of low-level bits in the input data is less than or equal to the preset value, the data determination module 23 is configured to output the original input data as the first intermediate data and set inversion flag data to Low.

For example, the input data has 8 bits. If the number of bits “0” in the input data is greater than half of the total number of bits of the input data, that is, greater than 4 (for example, the number of bits “0” is 5), Flag is 1, and the outputted first intermediate data is the inversion data of the input data. If the number of bits “0” in the input data is less than half of the total number of bits of the input data, for example, the number of bits “0” is 3, Flag is 0, and the outputted first intermediate data is the original input data.

The data being high means the data is “1”, and the data being low means the data is “0”. The data inversion means “0” is flipped to “1”, or “1” is flipped to “0”. The inversion of a data line or a signal line can be understood as changing from a high level to a low level, or changing from a low level to a high level.

In an implementation, the write operation circuit includes a serial-to-parallel conversion circuit 21. The serial-to-parallel conversion circuit 21 is connected between the DQ port 24 and the data determination module 23, and is configured to perform serial-to-parallel conversion on the first input data of the DQ port 24 to generate second input data. For example, the serial-to-parallel conversion circuit 21 performs serial-to-parallel conversion on 8-bit first input data DQ<7:0> to generate 128-bit second input data D2′<127:0> corresponding to the memory bank Bank0.

In an implementation, the second input data D2′<127:0> is divided into M groups, and the inversion flag data Flag has M bits. The M bits of the inversion flag data Flag are in one-to-one correspondence with the M groups of second input data, and each group of second input data has N bits, where N and M are integers greater than 1. When the number of low-level bits in an inputted group of second input data is greater than N/2, the data determination module 23 is configured to output the inversion data of the inputted group of second input data as a group of first intermediate data corresponding to the inputted group of second input data and set one bit of the inversion flag data corresponding to the inputted group of second input data to high. When the number of low-level bits in the inputted group of second input data is less than or equal to N/2, the data determination module 23 is configured to output the inputted group of second input data as the group of first intermediate data corresponding to the inputted group of second input data and set one bit of the inversion flag data corresponding to the inputted group of second input data to Low.

For example, the second input data D2′<127:0> is divided into 16 groups, and each group of second input data has 8 bits and corresponds to one bit of the inversion flag data Flag. Accordingly, the inversion flag data Flag has 16 bits, such as Flag<15:0>. The first intermediate data D1′<127:0> is divided into 16 groups accordingly. Each bit of the inversion flag data Flag corresponds one group of first intermediate data. For a group of second input data D2′<127:120>, if the number of bits “0” in D2′<127:120> is greater than 4, the corresponding bit of the inversion flag data Flag<15> is 1, the outputted group of first intermediate data D1′<127:120> is the inversion data of the group of second input data D2′<127:120>. If the number of bits “0” in D2′<127:120> is less than or equal to 4, the corresponding bit of the inversion flag data Flag<15> is 0, and the outputted group of first intermediate data D1′<127:120> is the group of second input data D2′<127:120>. Similarly, for the group of second input data D2′<15:8>, if the number of bits “0” in D2′<15:8> is greater than 4, the corresponding bit of the inversion flag data Flag<1> is 1, the outputted group of first intermediate data D1′<15:8> is the inversion data of the group of second input data D2′<15:8>. If the number of bits “0” in D2′<15:8> is less than or equal to 4, the corresponding bit of the inversion flag data Flag<1> is 0, and the outputted group of first intermediate data D1′<15:8> is the group of second input data D2′<15:8>. For the group of second input data D2′<7:0>, if the number of bits “0” in D2′<7:0> is greater than 4, the corresponding bit of the inversion flag data Flag<0> is 1, the outputted group of first intermediate data D1′<7:0> is the inversion data of the group of second input data D2′<7:0>. If the number of bits “0” in D2′<7:0> is less than or equal to 4, the corresponding bit of the inversion flag data Flag<0> is 0, and the outputted group of first intermediate data D1′<7:0> is the group of second input data D2′<7:0>. In this way, there is more data “0” in the first intermediate data D1′<127:0>.

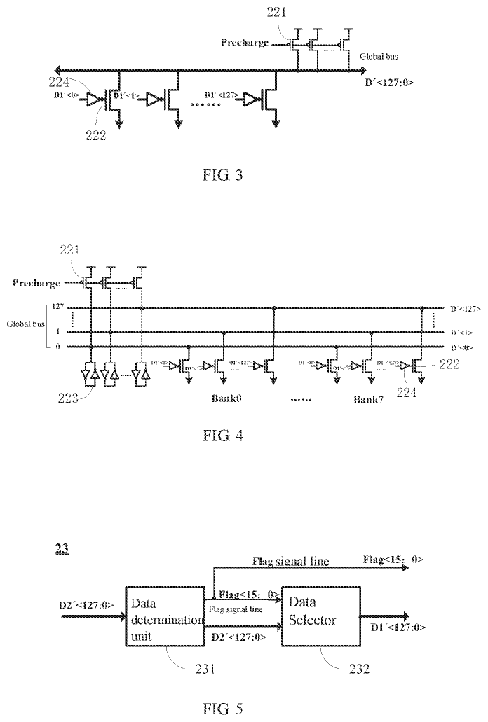

Furthermore, the semiconductor memory 20 of the present embodiment further includes a data buffer 22 and a precharge module 27. FIG. 3 shows a schematic circuit diagram of the data buffer 22 (corresponding to one memory bank 26) according to an implementation of the present embodiment. FIG. 4 shows a schematic circuit diagram of the data buffer 22 (corresponding to 8 memory banks 26) according to an implementation of the present embodiment.

As shown in FIG. 3 and FIG. 4, the data buffer 22 includes a plurality of Negative Channel Metal Oxide Semiconductor (NMOS) transistors 222 and a plurality of first inverters 224. A gate electrode of the NMOS transistor 222 is connected to the data determination module 23 through the corresponding first inverter 224, and a drain electrode of the NMOS transistor 222 is connected to the global bus. The first inverter 224 is configured to perform negation operation on the first intermediate data to generate the second intermediate data, such that the data buffer 22 determines whether to invert the global bus according to the second intermediate data. Since there is more data “1” in the first intermediate data, there is more data “0” in the second intermediate data.

The precharge module 27 is connected to a precharge signal line Precharge, and is configured to set an initial state of the global bus to Low. That is, the global bus of the semiconductor memory 20 of the present embodiment adopts a Precharge-High transmission configuration. Specifically, the precharge module 27 includes a plurality of Positive Channel Metal Oxide Semiconductor (PMOS) transistors 221 and a plurality of hold circuits 223. A gate electrode of the PMOS transistor 221 is connected to the precharge signal line, and a drain electrode of the PMOS transistor 221 is connected to the global bus. An input terminal and an output terminal of the hold circuit 223 are connected to the global bus to form a positive feedback circuit.

The function of Precharge is to set the initial state of each global bus to High, and the specific process is as follows. A pull-up pulse (about 2 ns) is generated on the precharge signal line Precharge, and the pull-up pulse pulls up the potential of the corresponding global bus for a moment, the hold circuit 223 forms a positive feedback, and the potential of the global bus is locked to the high level. However, the hold circuit 223 has a poor current pull-up capability and a poor current pull-down capability. When it needs to change the potential of a certain global bus to low level, the potential of the data line (the data line connected to the gate electrode of the corresponding NMOS transistor 222) corresponding to this global bus is pulled up (that is, a pulse, about 2 ns, is applied), and accordingly, the corresponding NMOS transistor 222 pulls down the potential of this global bus for a moment (the pull-down capability is stronger than the pull-up capability of the hold circuit 223), and then the potential of this global bus is locked to the low level through positive feedback, thereby achieving the inversion operation of the data line. There is more data “1” in the second intermediate data, and thus fewer inversions are required. Therefore, the IDD4W (write current) of the semiconductor memory will be reduced, such that the power consumption of the semiconductor memory can be reduced.

In an example, there are a plurality of global buses, and the plurality of global buses are arranged in M groups, where M is an integer greater than 1. Each global bus transmits one bit of the global bus data. For example, there are 128 global buses, the global bus <0> transmits the global bus data D′<0>, the global bus <1> transmits the global bus data D′<1>; . . . ; the global bus <127> transmits the global bus data D′<127>. The 128 global buses are arranged in 16 groups.

In an example, each inversion flag data Flag corresponds to one group of global bus data. Accordingly, there are 16 Flag signal lines (inversion flag signal lines), and the Flag data (inversion flag data) has 16 bits, for example, Flag<15:0>. Each Flag signal line transmits one bit of the Flag data. For example, a Flag signal line <0> transmits the Flag data Flag<0> and corresponds to the global bus data D′<7:0>, the Flag data Flag <0> indicates whether D′<0:7> is the inverted second intermediate data; a Flag signal line <1> transmits the Flag data Flag<1> and corresponds to the global bus data D′<15:8>, the Flag data Flag<1> indicates whether D′<15:8> is the inverted second intermediate data; . . . ; a Flag signal line <15> transmits the Flag data Flag<15> and corresponds to the global bus data D′<127:120>, the Flag data Flag<15> indicates whether D′<127:120> is the inverted second intermediate data.

The second intermediate data is the inverted data of the first intermediate data D1′<127:120>. Therefore, when Flag<15>=1, the global bus data D′<127:120>=D1′<127:120>; and when Flag<15>=0, the global bus data D′<127:120> is the inversion data of D1′<127:120>. Similarly, when Flag<1>=1, the global bus data D′<15:8>=D1′<15:8>; and when Flag<1>=0, the global bus data D′<15:8> is the inversion data of D1′<15:8>. When Flag<0>=1, the global bus data D′<7:0>=D1′<7:0>; and when the Flag<0>=0, the global bus data D′<7:0> is the inversion data of D1′<7:0>.

In this way, there is more data “1” in the global bus data D′<127:0> transmitted on the global bus. Accordingly, for the semiconductor memory 20 shown in FIG. 2, there is more data “1” in the 256-bit global bus data (including the 128-bit global bus data corresponding to DQ<7:0> and the 128-bit global bus data corresponding to DQ<15:8>).

In an implementation, as shown in FIG. 5, the data determination module 23 includes a data determination unit 231 and a data selector 232.

An input terminal of the data determination unit 231 is connected to the serial-to-parallel conversion circuit 21. An output terminal of the data determination unit 231 is connected to the Flag signal line and an input terminal of the data selector 232. The data determination unit 231 is configured to set the Flag data to high when the number of low-level bits in the second input data is greater than the preset value, and set the Flag data to low when the number of low-level bits in the second input data is less than or equal to the preset value.

An input terminal of the data selector 232 is connected to the data determination unit 231 and is configured to receive the second input data through the data determination unit 231. An input terminal of the data selector 232 further receives the Flag data through the Flag signal line. An output terminal of the data selector 232 is connected to the input terminal of the first inverter 224. The data selector 232 is configured to output the inversion data of the second input data as the first intermediate data when the Flag data is high, and output the original second input data as the first intermediate data when the Flag data is low.

In an implementation, the data selector 232 includes data select units 232′, and each data select unit 232′ is configured to process one bit of the Flag data and one group of second input data. For example, there are 16 data select units 232′, each of which corresponds to one of the 16 groups of second input data and one bit of the Flag data.

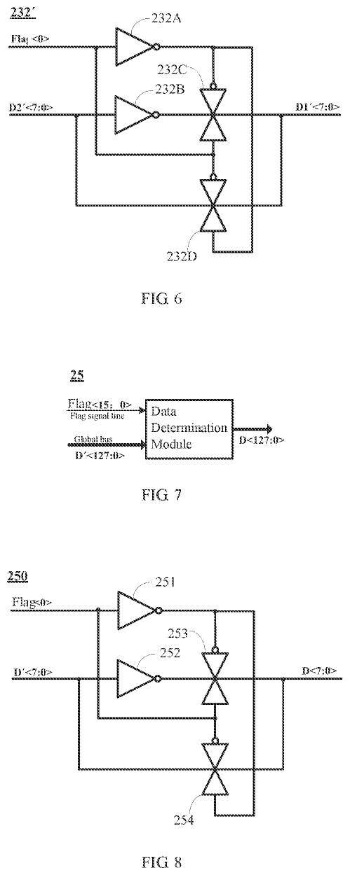

FIG. 6 shows an implementation of an exemplary data select unit 232′. As shown in FIG. 6, the data select unit 232′ includes a second inverter 232A, a third inverter 232B, a first transmission gate 232C, and a second transmission gate 232D.

An input terminal of the second inverter 232A receives the Flag data through the Flag signal line. An input terminal of the third inverter 232B is connected to the data determination unit 231 and is configured to receive the second input data from the data determination unit 231. An input terminal of the first transmission gate 232C is connected to an output terminal of the third inverter 232B, and an output terminal of the first transmission gate 232C is connected to the input terminal of the first inverter 224 and is configured to output the first intermediate data. A negative control terminal (the upper control terminal in FIG. 6) of the first transmission gate 232C is connected to an output terminal of the second inverter 232A, and a positive control terminal (the lower control terminal in FIG. 6) of the first transmission gate 232C receives the Flag data through the Flag signal line. An input terminal of the second transmission gate 232D is connected to the data determination unit 231 and is configured to receive the second input data from the data determination unit 231. An output terminal of the second transmission gate 232D is connected to the input terminal of the first inverter 224 and is configured to output the first intermediate data. A negative control terminal of the second transmission gate 232D receives the Flag data through the Flag signal line, and a positive control terminal of the second transmission gate 232D is connected to an output terminal of the second inverter 232A.

Taking Flag<0> and the second input data D2′<7:0> as an example, as shown in FIG. 6, when Flag=1, the first intermediate data D1′<7:0> is the inversion data of the second input data D2′<7:0>; and when Flag=0, the first intermediate data D1′<7:0> is the second input data D2′<7:0>.

It should be noted that one group, including the third inverter 232B, the first transmission gate 232C and the second transmission gate 232D, is configured to process one bit of the second input data and output one corresponding bit of the second intermediate data. That is, for 8-bit second input data D2′<7:0>, eight groups of the third inverter 232B, the first transmission gate 232C and the second transmission gate 232D are required, and thus 8-bit first intermediate data D1′<7:0> can be outputted.

In view of the above, when the Flag data is 1, the global bus data D′<127:0> is the inversion data of the second input data D2′<127:0>; and when the Flag data is 0, the global bus data D′<127:0> is the original second input data D2′<127:0>.

As shown in FIG. 1, FIG. 2 and FIG. 7, the write operation circuit of the present embodiment further includes a data receiving module 25. An input terminal of the data receiving module 25 is connected to the global bus and the inversion flag signal line, and an output terminal of the data receiving module 25 is connected to the memory bank 26. The data receiving module 25 is configured to determine, according to the Flag data, whether to invert the global bus data (i.e., decode the global bus data) and write the decoded data (i.e., write date) into the memory bank 26. For example, when the Flag data is high, the inversion data of the global bus data is outputted as the write data; and when the Flag data is low, the original global bus data is outputted as the write data.

As a result, the write data is reverted to the input data of the semiconductor memory. Accordingly, neither data nor functions of an external port such as the DQ port 24 and a DBI port (not shown in the figures) of the semiconductor memory 20 will be changed.

In one embodiment, the data receiving module 25 may include a plurality of data receiving units 250, and each of the plurality of the data receiving units 250 is configured to process one bit of the inversion flag data and one group of global bus data. For example, there may be 16 data receiving units 250, each of which corresponds to one of the 16 groups of global bus data and one bit of the inversion flag data. FIG. 8 illustrates an implementation manner of the data receiving unit 250.

As shown in FIG. 8, the data receiving unit 250 includes a fourth inverter 251, a fifth inverter 252, a third transmission gate 253, and a fourth transmission gate 254.

An input terminal of the fourth inverter 251 receives the inversion flag data through the inversion flag signal line. An input terminal of the fifth inverter 252 receives the global bus data through the global bus. An input terminal of the third transmission gate 253 is connected to an output terminal of the fifth inverter 252. An output terminal of the third transmission gate 253 is connected to the memory bank 26 and is configured to output the write data to the memory bank 26. A negative control terminal (the upper control terminal in FIG. 8) of the third transmission gate 253 is connected to an output terminal of the fourth inverter 251, and a positive control terminal of the third transmission gate 253 receives the inversion flag data through the inversion flag signal line. An input terminal of the fourth transmission gate 254 receives the global bus data through the global bus. An output terminal of the fourth transmission gate 254 is connected to the memory bank 26 and is configured to output the write data to the memory bank 26. A negative control terminal (the upper control terminal in FIG. 8) of the fourth transmission gate 254 receives the inversion flag data through the inversion flag signal line, and a positive control terminal (the lower control terminal in FIG. 8) of the fourth transmission gate 254 is connected to the output terminal of the fourth inverter 251.

Taking Flag<0> and the global bus data D′<7:0> as an example, as shown in FIG. 8, when Flag=1, the write data D<7:0> is the inversion data of the global bus data D′<7:0>; and when Flag=0, the write data D<7:0> is the global bus data D′<7:0>, that is, D<7:0>=D′<7:0>.

It should be noted that one group, including the fifth inverter 252, the third transmission gate 253, and the fourth transmission gate 254, is configured to process one bit of the global bus data and output one corresponding bit of the write data. That is, for 8-bit global bus data D′<7:0>, eight groups of the fifth inverter 252, the third transmission gate 253, and the fourth transmission gate 254 are required, and thus 8-bit write data D<7:0> can be outputted.

According to the semiconductor memory 20 of the present embodiment, in the process of writing data (DQ<7:0>=<00000000>; DQ<15:8>=<00000000>) into the semiconductor memory 20, the global bus data has 256 bits. If it needs to invert the 256-bit global bus data, it only needs to invert 32-bit inversion flag data, such that the IDD4W current will be reduced significantly.

In practical applications, the semiconductor memory 20 of the present embodiment also includes other structures such as a sense amplifier and a precharge circuit, which are not repeated in this embodiment because they belong to the existing technologies.

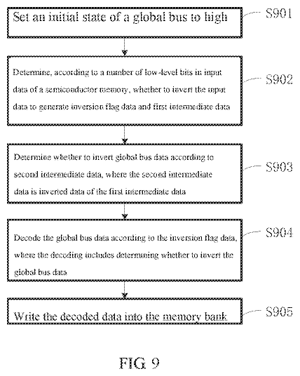

FIG. 9 shows a schematic flowchart of a write operation method according to an implementation of the present embodiment. The write operation method can be applied in the above semiconductor memory 20. As shown in FIG. 9, the write operation method includes the following steps.

In step S901, an initial state of the global bus is set to high.

In step S902, according to the number of low-level bits in the input data of the semiconductor memory, it is determined whether to invert the input data to generate inversion flag data and first intermediate data.

In step S903, it is determined whether to invert global bus data according to second intermediate data, where the second intermediate data is inverted data of the first intermediate data.

In step S904, the global bus data is decoded according to the inversion flag data, where the decoding includes determining whether to invert the global bus data.

In step S905, the decoded data is written into the memory bank.

In one embodiment, the step S902 may include: performing serial-to-parallel conversion on first input data of a DQ port to generate second input data; and determining, according to a number of low-level bits in the second input data, whether to invert the second input data to generate inversion flag data and first intermediate data.

In one embodiment, the step of determining, according to the number of low-level bits in the second input data, whether to invert the second input data to generate inversion flag data and first intermediate data includes the following steps. The second input data is divided into M groups, where each group of second input data has N bits. When the number of low-level bits in an inputted group of second input data is greater than N/2, inversion data of the inputted group of second input data is outputted as a corresponding group of first intermediate data, and one bit of the inversion flag data corresponding to the inputted group of second input data is set to high. When the number of low-level bits in the inputted group of second input data is less than or equal to N/2, the inputted group of second input data is outputted as the corresponding group of first intermediate data, and one bit of the inversion flag data corresponding to the inputted group of second input data is set to low.

The write operation circuit provided by embodiments of the present disclosure is used in a semiconductor memory whose global bus transmission structure is a Precharge-High architecture. The number of inversions of the internal global bus can be reduced, the current may be reduced significantly, and power consumption may be decreased.

In the description of this specification, descriptions of reference terms “one embodiment”, “some embodiments”, “example”, “specific example”, or “some examples” mean that a particular feature, structure, material, or characteristic described in in conjunction with the embodiment is included in at least one embodiment of the present disclosure. Moreover, the described specific features, structures, materials or characteristics can be combined in any one or more embodiments or examples in a suitable manner. In addition, if there is no conflict with each other, those of ordinary skill in the art can combine different embodiments or examples and combine the features of the different embodiments or examples described in this specification.

Furthermore, the described features, structures or characteristics may be combined in one or more embodiments in any suitable manner. However, those of ordinary skill in the art will understand that the technical solutions of the present disclosure can be practiced without one or more of the specific details, or practiced by using other methods, components, materials, devices, steps, and the like. In other cases, well-known structures, methods, devices, implementations, materials, or operations are not shown or described in detail to avoid obscuring various aspects of the present application.

The terms “first” and “second” are only used for descriptive purposes, and should not be understood as indicating or implying relative importance or implicitly indicating the number of described technical features. Thus, the feature defined with “first” and “second” may explicitly or implicitly include one or more of such features. In the description of the present application, “plurality” refers to two or more than two, unless otherwise specifically defined.

It should be noted that although various steps of the method in this disclosure are described in a specific order in the drawings, it is not required or implied that the steps must be performed in the specific order, or that all the shown steps must be performed to achieve the desired result. Additionally or alternatively, some steps may be omitted, multiple steps may be combined into one step for execution, and/or one step may be divided into multiple steps for execution, etc. The above drawings are merely schematic illustrations of the processing included in the method according to the exemplary embodiments of the present disclosure, and are not intended for limitation. It is easy to understand that the processing shown in the above drawings does not indicate or limit the time sequence of these processing. In addition, it is easy to understand that these processes can be executed synchronously or asynchronously in, for example, multiple modules.

Although the spirit and principle of the present disclosure have been described with reference to specific embodiments, it should be understood that the present disclosure is not limited to the specific embodiments disclosed, and the division of various aspects does not mean that the features in these aspects cannot be combined for benefits, this division is only for the convenience of description. This disclosure is intended to cover various modifications and equivalent arrangements included in the spirit and scope of the appended claims.

The foregoing descriptions are merely specific embodiments of the present disclosure, but are not intended to limit the protection scope of the present disclosure. Any modifications or substitutions easily made by those of ordinary skill in the art in light of the teachings disclosed herein shall fall within the protection scope of the present disclosure. Therefore, the protection scope of the present disclosure shall be subject to the protection scope of the claims.

What is claimed is:

1. A write operation circuit used in a semiconductor memory, comprising:
a data determination module, wherein the data determination module is configured to determine, according to a number of low-level bits in input data of the semiconductor memory, whether to invert the input data to generate inversion flag data and first intermediate data;
a data buffer, wherein the data buffer comprises a plurality of NMOS transistors and a plurality of first inverters, a gate electrode of each of the plurality of NMOS transistors is connected to the data determination module through a respective one of the plurality of first inverters to receive second intermediate data, a drain electrode of each of the plurality of NMOS transistors is connected to a global bus, the data buffer is configured to determine whether to invert the global bus according to second intermediate data, wherein the second intermediate data is inverted data of the first intermediate data;
a data receiving module connected to a memory bank, wherein the data receiving module is configured to receive global bus data through the global bus and receive the inversion flag data through an inversion flag signal line, and the data receiving module is configured to decode the global bus data according to the inversion flag data and write decoded data into the memory bank of the semiconductor memory, the decoding comprises determining whether to invert the global bus data; and
a precharge module connected to a precharge signal line and configured to set an initial state of the global bus to High.

2. The write operation circuit according to claim 1, further comprising: a serial-to-parallel conversion circuit connected between a Data Queue (DQ) port of the semiconductor memory and the data determination module, wherein the serial-to-parallel conversion circuit is configured to perform serial-to-parallel conversion on first input data of the DQ port to generate second input data;
wherein the data determination module is configured to determine, according to a number of low-level bits in the second input data, whether to invert the second input data to generate the inversion flag data and first intermediate data.

3. The write operation circuit according to claim 2, wherein the second input data is divided into M groups, the inversion flag data has M bits, the M bits of the inversion flag data and the M groups of second input data are in one-to-one correspondence, each of the M groups of second input data has N bits, N and M are integers greater than 1;
when a number of low-level bits in an inputted group of second input data is greater than N/2, the data determination module is configured to output inversion data of the inputted group of second input data as a group of first intermediate data corresponding to the inputted group of second input data and set one bit of the inversion flag data corresponding to the inputted group of second input data to high;
when the number of low-level bits in the inputted group of second input data is less than or equal to N/2, the data determination module is configured to output the inputted group of second input data as the group of first intermediate data corresponding to the inputted group of second input data and set one bit of the inversion flag data corresponding to the inputted group of second input data to low.

4. The write operation circuit according to claim 2, wherein the data determination module comprises:
a data determination unit, wherein an input terminal of the data determination unit is connected to the serial-to-parallel conversion circuit, an output terminal of the data determination unit is connected to the inversion flag signal line, and the data determination unit is configured to set the inversion flag data to high when the number of low-level bits in the second input data is greater than a preset value, and set the inversion flag data to Low when the number of low-level bits in the second input data is less than or equal to the preset value; and
a data selector, wherein an input terminal of the data selector is connected to the data determination unit to receive the second input data through the data determination unit, an input terminal of the data selector further receives the inversion flag data through the inversion flag signal line, an output terminal of the data selector is connected to an input terminal of the first inverter, and the data selector is configured to output inversion data of the second input data as the first intermediate data when the inversion flag data is high, and output the original second input data as the first intermediate data when the inversion flag data is low.

5. The write operation circuit according to claim 4, wherein the data selector comprises a plurality of data select units, and each of the plurality of data select units comprises:
a second inverter, wherein an input terminal of the second inverter receives the inversion flag data through the inversion flag signal line;
a third inverter, wherein an input terminal of the third inverter is connected to the data determination unit and is configured to receive the second input data from the data determination unit;
a first transmission gate, wherein an input terminal of the first transmission gate is connected to an output terminal of the third inverter, an output terminal of the first transmission gate is connected to the input terminal of the first inverter and is configured to output the first intermediate data, a negative control terminal of the first transmission gate is connected to an output terminal of the second inverter, and a positive control terminal of the first transmission gate receives the inversion flag data through the inversion flag signal line; and
a second transmission gate, wherein an input terminal of the second transmission gate is connected to the data determination unit and is configured to receive the second input data from the data determination unit, an output terminal of the second transmission gate is connected to the input terminal of the first inverter and is configured to output the first intermediate data, a negative control terminal of the second transmission gate receives the inversion flag data through the inversion flag signal line, and a positive control terminal of the second transmission gate is connected to the output terminal of the second inverter.

6. The write operation circuit according to claim 3, wherein the global bus data is arranged in M groups, and the M bits of the inversion flag data and the M groups of global bus data are in one-to-one correspondence, the data receiving module comprises M data receiving units, and each of the M data receiving units is connected to the memory bank and is configured to decode, according to one bit of the inversion flag data, corresponding group of global bus data.

7. The write operation circuit according to claim 6, wherein each of the M data receiving units comprises:
a fourth inverter, wherein an input terminal of the fourth inverter receives the inversion flag data through the inversion flag signal line;
a fifth inverter, wherein an input terminal of the fifth inverter receives the global bus data through the global bus;
a third transmission gate, wherein an input terminal of the third transmission gate is connected to an output terminal of the fifth inverter, an output terminal of the third transmission gate is connected to the memory bank and is configured to output the decoded data to the memory bank, a negative control terminal of the third transmission gate is connected to an output terminal of the fourth inverter, and a positive control terminal of the third transmission gate receives the inversion flag data through the inversion flag signal line; and
a fourth transmission gate, wherein an input terminal of the fourth transmission gate receives the global bus data through the global bus, an output terminal of the fourth transmission gate is connected to the memory bank and is configured to output the decoded data to the memory bank, a negative control terminal of the third transmission gate receives the inversion flag data through the inversion flag signal line, and a positive control terminal of the third transmission gate is connected to the output terminal of the fourth inverter.

8. The write operation circuit according to claim 1, wherein the precharge module comprises a plurality of PMOS transistors and a plurality of hold circuits, a gate electrode of each of the plurality of PMOS transistors is connected to the precharge signal line, a drain electrode of each of the plurality of PMOS transistors is connected to the global bus, and an input terminal and an output terminal of each of the plurality of hold circuits are both connected to the global bus.

9. A semiconductor memory, comprising a write operation circuit, wherein the write operation circuit comprises:
a data determination module, wherein the data determination module is configured to determine, according to a number of low-level bits in input data of the semiconductor memory, whether to invert the input data to generate inversion flag data and first intermediate data;
a data buffer, wherein the data buffer comprises a plurality of NMOS transistors and a plurality of first inverters, a gate electrode of each of the plurality of NMOS transistors is connected to the data determination module through a respective one of the plurality of first inverters to receive second intermediate data, a drain electrode of each of the plurality of NMOS transistors is connected to a global bus, the data buffer is configured to determine whether to invert the global bus according to second intermediate data, where the second intermediate data is inverted data of the first intermediate data;
a data receiving module connected to a memory bank, wherein the data receiving module is configured to receive global bus data through the global bus and receive the inversion flag data through the inversion flag signal line, and the data receiving module is configured to decode the global bus data according to the inversion flag data and write decoded data into the memory bank of the semiconductor memory, the decoding comprises determining whether to invert the global bus data; and
a precharge module connected to a precharge signal line and configured to set an initial state of the global bus to high.

10. A write operation method used in a semiconductor memory, comprising:
setting an initial state of a global bus to high;
determining, according to a number of low-level bits in input data of the semiconductor memory, whether to invert the input data to generate inversion flag data and first intermediate data;
determining whether to invert global bus data according to second intermediate data, wherein the second intermediate data is inverted data of the first intermediate data;
decoding the global bus data according to the inversion flag data, wherein the decoding comprises determining whether to invert the global bus data; and
writing decoded data into a memory bank.

11. The write operation method according to claim 10, wherein the determining, according to the number of low-level bits in input data of the semiconductor memory, whether to invert the input data to generate the inversion flag data and the first intermediate data comprises:
performing serial-to-parallel conversion on first input data of a Data Queue (DQ) port to generate second input data; and
determining, according to a number of low-level bits in the second input data, whether to invert the second input data to generate the inversion flag data and the first intermediate data.

12. The write operation method according to claim 11, wherein the determining, according to the number of low-level bits in the second input data, whether to invert the second input data to generate the inversion flag data and the first intermediate data comprises:
dividing the second input data into M groups, wherein each group of second input data has N bits, and M and N are integers greater than 1;
dividing the second input data into M groups, wherein each group of second input data has N bits, and M and N are integers greater than 1;
when a number of low-level bits in an inputted group of second input data is greater than N/2, outputting inversion data of the inputted group of second input data as a corresponding group of first intermediate data and setting one bit of the inversion flag data corresponding to the inputted group of second input data to high; and
when the number of low-level bits in the inputted group of second input data is less than or equal to N/2, outputting the inputted group of second input data as the corresponding group of first intermediate data and setting one bit of the inversion flag data corresponding to the inputted group of second input data to low.
